(19) United States
(12) Patent Application Publication
(10) Pub. No.: US 2013/0224936 A1
(43) Pub. Date: Aug. 29, 2013

(54) METHODS OF MANUFACTURING A SEMICONDUCTOR DEVICE

(71) Applicant: SAMSUNG ELECTRONICS CO., LTD., (US)

(72) Inventors: Jongwook Lee, Yongin-si (KR); Donggu Yi, Seoul (KR)

(73) Assignee: SAMSUNG ELECTRONICS CO., LTD., Suwon-si (KR)

(21) Appl. No.: 13/690,394

(22) Filed: Nov. 30, 2012

(30) Foreign Application Priority Data
Feb. 23, 2012 (KR) 10-2012-0018576

(51) Int. Cl. H01L 21/8234

(52) U.S. Cl. CPC H01L 21/823431
USPC 438/492

(57) ABSTRACT

Methods of manufacturing a semiconductor device are provided. The method includes constructing and arranging a semiconductor substrate to include a first active region and a second active region and forming mold patterns on the semiconductor substrate. The mold patterns have openings that expose a top surface of the semiconductor substrate. A plurality of first semiconductor fins are formed in openings at the first active region and a plurality of second semiconductor fins in openings at the second active region and selectively recessing top surfaces of the mold patterns. A recessed depth of the mold patterns on the first active region is different than a recessed depth of the mold patterns on the second active region. A gate electrode is formed over the first and second semiconductor fins. A distance between a first semiconductor fin of the plurality of first semiconductor fins and a second semiconductor fin of the plurality of second semiconductor fins adjacent the first semiconductor fin is greater than a distance between two or more first semiconductor fins of the plurality of first semiconductor fins that are adjacent each other.

### CROSS-REFERENCE TO RELATED APPLICATIONS

This U.S. non-provisional patent application claims priority under 35 U.S.C. §119 to Korean Patent Application No. 10-2012-0018576, filed on Feb. 23, 2012, the entirety of which is incorporated by reference herein.

### BACKGROUND

The inventive concepts relate to methods of manufacturing a semiconductor device and, more particularly, to methods of manufacturing a semiconductor device including a fin field effect transistor (FinFET).

A semiconductor device may include an integrated circuit consisting of metal-oxide-semiconductor field effect transistors (MOSFETs). As a size and a design rule of the semiconductor device become more reduced, a size of a MOSFET can be reduced for purposes related to scaling. The scaling down of the MOSFET may cause a short channel effect, such that operation characteristic of the semiconductor device may deteriorate. Various research efforts have been conducted for overcoming limitations caused by the high integration of a semiconductor device and for forming a semiconductor device having improved performance.

### SUMMARY

Embodiments of the inventive concepts may provide methods of manufacturing a semiconductor device having an improved degree of integration and an improved operation characteristic.

In an aspect, provided is a method of manufacturing a semiconductor device. A semiconductor substrate is constructed and arranged to include a first active region and a second active region. Mold patterns are formed on the semiconductor substrate. The mold patterns have openings that expose a top surface of the semiconductor substrate. A plurality of first semiconductor fins are formed in openings at the first active region and a plurality of second semiconductor fins in openings at the second active region. Top surfaces of the mold patterns are selectively recessed. A recessed depth of the mold patterns on the first active region is different than a recessed depth of the mold patterns on the second active region. A gate electrode is formed over the first and second semiconductor fins. A distance between a first semiconductor fin of the plurality of first semiconductor fins and a second semiconductor fin of the plurality of second semiconductor fins adjacent the first semiconductor fin is greater than a distance between two or more first semiconductor fins of the plurality of first semiconductor fins that are adjacent each other.

In an embodiment, distances between the mold patterns are substantially uniform with respect to each other along a surface of the semiconductor substrate.

In an embodiment, the semiconductor substrate includes a device isolation pattern that defines the first and second active regions.

In an embodiment, the device isolation pattern is between the first semiconductor fin and the second semiconductor fin.

In an embodiment, a width of the device isolation pattern is greater than a distance between the two or more first semiconductor fins adjacent each other.

In an embodiment, a height of the device isolation pattern is greater than each vertical distance extending from a top surface of the semiconductor substrate to a top surface of the first and second semiconductor fins.

In an embodiment, forming the first and second semiconductor fins comprises: performing a selective epitaxial growth process using the semiconductor substrate exposed by the openings of the mold patterns as a seed.

In an embodiment, vertical distances from a top surface of the semiconductor substrate to top surfaces of the first and second semiconductor fins, respectively, are substantially uniform.

In an embodiment, forming the mold patterns comprises: stacking a first insulating layer, a second insulating layer, and a hard mask layer, each having an etch selectivity; and patterning the hard mask layer, the second insulating layer, and the first insulating layer to form the mold patterns, each of the mold patterns including a first insulating pattern, a second insulating pattern, and a hard mask pattern sequentially stacked.

In an embodiment, selectively recessing the top surfaces of the mold patterns comprises: exposing top surfaces of the second insulating patterns at the first and second active regions; and exposing top surfaces of the first insulating patterns at the second active region.

In another aspect, provided is a method of manufacturing a semiconductor device. A semiconductor substrate is provided including a first active region and a second active region, the first and second active regions defined by device isolation patterns. A plurality of mold patterns is formed. The mold patterns have openings that expose the semiconductor substrate of the first and second active regions. An epitaxial growth process is performed to form semiconductor fins in the openings, respectively. Top surfaces of the mold patterns are selectively recessed to expose sidewalls of the semiconductor fins. A gate electrode is formed over the semiconductor fins having the exposed sidewalls. Exposing the sidewalls of the semiconductor fins comprises: recessing the top surfaces of the mold patterns on the first active region by a first depth to form first semiconductor fins and recessing the top surfaces of the mold patterns on the second active region by a second depth greater than the first depth to form second semiconductor fins.

In an embodiment, a width of each of the device isolation patterns is greater than a distance between the first semiconductor fins adjacent to each other.

In an embodiment, the mold patterns expose top surfaces of the device isolation patterns.

In an embodiment, the first semiconductor fin is adjacent the second semiconductor fin, and a distance between the first semiconductor fin and the second semiconductor fin is greater than a distance between two first semiconductor fins adjacent each other.

In an embodiment, vertical distances from a top surface of the semiconductor substrate to top surfaces of the first and second semiconductor fins, respectively, are substantially equal to each other.

In another aspect, provided is a method of manufacturing a semiconductor device. A first active region and a second active region are formed at a substrate. At least one insulating layer is formed on the substrate. At least one first opening is formed in the at least one insulating layer. The at least one first opening exposes the substrate at the first active region. At least one second opening is formed in the at least one insulating layer. The at least one second opening exposes the substrate at the second active region. A fin of a first field effect transistor (FinFET) is formed in the at least one first opening. A fin of a second FinFET is formed in the at least one second opening. A channel width at the first FinFET is different than a channel width at the second FinFET.

In an embodiment, a plurality of first semiconductor fins is formed at the at least one first opening at the first active region and a plurality of second semiconductor fins is formed at the at least one second opening at the second active region. A distance between a first semiconductor fin of the plurality of first semiconductor fins and a second semiconductor fin of the plurality of second semiconductor fins adjacent the first semiconductor fin is greater than a distance between two or more first semiconductor fins of the plurality of first semiconductor fins that are adjacent each other.

In an embodiment, the at least one insulating layer is etched to form mold patterns on the substrate. The mold patterns are separated from each other by the at least one first opening and the at least one second opening. Top surfaces of the mold patterns are selectively recessed. A recessed depth of mold patterns on the first active region is different than a recessed depth of mold patterns on the second active region.

In an embodiment, the first FinFET and the second FinFET have different electrical characteristics with respect to each other.

In an embodiment, a first separation structure is formed from the at least one insulating layer. The first separation structure is between the plurality of first semiconductor fins. A second separation structure is formed from the at least one insulating layer. The second separation structure is between the plurality of second semiconductor fins. A vertical distance from a top surface of the first separation structure to a top surface of the first semiconductor fin is different than a vertical distance from a top surface of the second separation structure to a top surface of the second semiconductor fin.

### BRIEF DESCRIPTION OF THE DRAWINGS

The inventive concept will become more apparent in view of the attached drawings and accompanying detailed description.

FIGS. 1 to 9 are cross-sectional views illustrating a method of manufacturing a semiconductor device according to some embodiments of the inventive concepts;

FIGS. 10 to 12 are cross-sectional views illustrating a method of manufacturing a semiconductor device according to other embodiments of the inventive concepts;

FIG. 13 is a circuit diagram of an inverter including a semiconductor device according to embodiments of the inventive concepts;

FIG. 14 is a circuit diagram of a static random access memory (SRAM) device including a semiconductor device according to embodiments of the inventive concepts;

FIG. 15 is a schematic block diagram illustrating an electronic system including a semiconductor device according to embodiments of the inventive concepts; and

FIG. 16 is a schematic block diagram illustrating a memory card including a semiconductor device according to embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

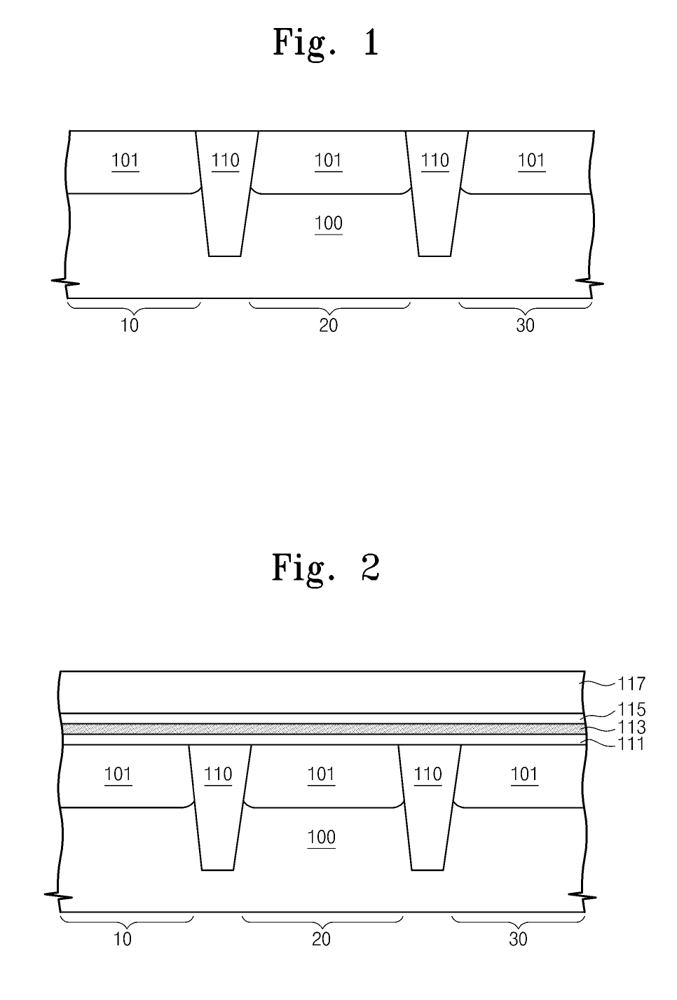

Hereinafter, methods of manufacturing a semiconductor device according to embodiments will be described with reference to FIGS. 1 to 10.

Referring to FIG. 1, a semiconductor substrate 100 may include a first active region 10, a second active region 20, and a third active region 30. According to embodiments of the inventive concepts, field effect transistors having effective channel widths different from each other may be formed in the first to third active regions 10, 20, and 30, respectively. For example, a first field effect transistor may be formed in the first active region 10, a second field effect transistor may be formed in the second active region 20, and a third field effect transistor may be formed in the third active region 30. Additionally, an NMOS field effect transistor or a PMOS field effect transistor may be formed in at least one of the first to third active regions 10, 20, and 30. Accordingly, an NMOS field effect transistor and a PMOS field effect transistor may each be formed at the semiconductor substrate 100.

The semiconductor substrate 100 may be a single-crystalline silicon substrate. Alternatively, the semiconductor substrate 100 may be a silicon-on-insulator (SOI) substrate, a germanium substrate, a germanium-on-insulator (GOI) substrate, a silicon-germanium substrate, or a substrate including an epitaxial layer formed by a selective epitaxial growth (SEG) process or related process.

The first to third active regions 10, 20, and 30 may be defined by device isolation patterns 110 formed in the semiconductor substrate 100. Each of the first to third active regions 10, 20, and 30 may include a well 101 that is doped with n-type dopants or p-type dopants. Alternatively, if a p-type semiconductor substrate 100 is used, n-type wells 101 may be selectively formed in the active regions 10, 20, and 30.

The device isolation patterns 110 may electrically separate the wells 101 formed in the semiconductor substrate 100 from each other. Additionally, if field effect transistors having different electrical characteristics with respect to each other may be formed in the first to third active regions 10, 20, and 30, respectively, the device isolation patterns 110 may decrease an electrical influence between the field effect transistors.

The semiconductor substrate 100 may be patterned to form device isolation trenches defining the active regions 10, 20, and 30. The device isolation trenches may be filled with an insulating material to form the device isolation patterns 110.

Here, in forming the device isolation trenches, one or more device isolation masks (not shown) may be formed on the semiconductor substrate 100. The semiconductor substrate 100 may be anisotropically etched using the device isolation masks as etch masks. The device isolation trench may have a sufficient depth and width required for electrically separating the wells 101 from each other. In this manner, the deeper the depth of the device isolation trench, the more efficient and/or effective the electrical isolation between the wells 101.

The insulating material used to form the device isolation patterns 110 may include at least one of silicon oxide and low-k dielectrics having a dielectric constant lower than that of silicon oxide.

Additionally, forming the device isolation patterns 110 may further include forming a liner structure (not shown) covering an inner sidewall of the device isolation trench. In some embodiments, the liner structure may include a thermal oxide layer that is formed by thermally oxidizing the inner sidewall of the device isolation trench and a nitride liner conformally covering a resultant structure where the thermal oxide layer is formed.

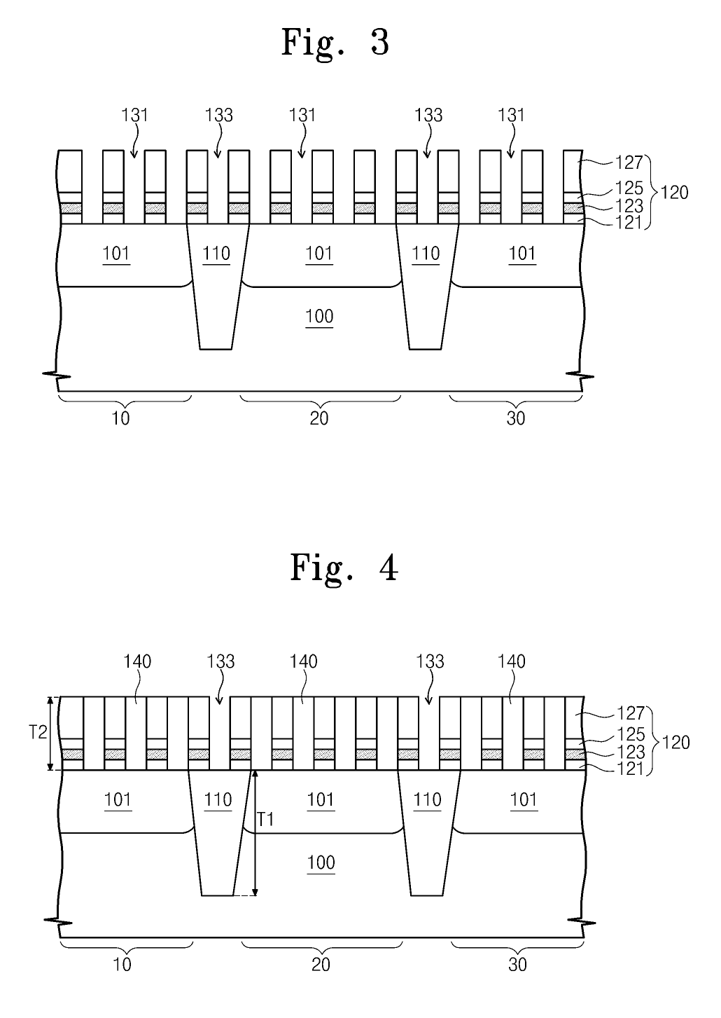

Subsequently, referring to FIGS. 2 and 3, mold patterns 120 having fin-openings 131 may be formed on the semiconductor substrate 100 where the first to third active regions 10, 20, and 30 are defined. The openings 131 can be formed on a well 101 at the substrate 100.

In some embodiments, forming the mold patterns 120 may include sequentially stacking a plurality of insulating layers 111, 113, 115, respectively, and a hard mask layer 117 on the semiconductor substrate 100, forming a mask pattern (not shown) on the hard mask layer 117, and successively and anisotropically etching the hard mask layer 117 and the insulating layers 111, 113, 115 using the mask pattern until the semiconductor substrate 100 and the device isolation pattern 110 are exposed.

In more detail, referring to FIG. 2, first to third insulating layers 111, 113, and 115 and the hard mask layer 117 may be sequentially stacked on the semiconductor substrate 100 having the first to third active regions 10, 20, and 30. Here, thicknesses of the first to third insulating layers 111, 113, and 115 may be substantially equal to each other. The first to third insulating layers 111, 113, and 115 may be formed of insulating materials different from each other, respectively. For example, the first to third insulating layers 111, 113, and 115 may be formed of oxide, nitride, and/or oxynitride. In other embodiments, different kinds of insulating layers, that have an etch selectivity with respect to each other may be alternately stacked to form the first to third insulating layers 111, 113, and 115. The hard mask layer 117 may be formed of a material having an etch selectivity or other properties with respect to the third insulating layer 115. For example, the hard mask layer 117 may be formed of oxide, nitride, and/or oxynitride. The hard mask layer 117 may be formed to be thicker than each of the first to third insulating layers 111, 113, and 115.

Referring to FIG. 3, subsequently, the hard mask layer 117 and the third to first insulating layers 115, 113, and 111 may be successively and anisotropically etched using the mask pattern (not shown) disposed on the hard mask layer 117. Thus, the mold patterns 120 may be formed from the insulating layers 115, 113, 111 and the hard mask layer 117, the mold patterns 120 including fin openings 131.

In some embodiments, each of the mold patterns 120 may include a plurality of layers sequentially stacked. In other words, each of the mold patterns 120 may include first, second, and third insulating patterns 121, 123, 125 and a hard mask pattern 127 that are sequentially stacked.

In some embodiments, distances between the mold patterns 120 are substantially uniform along the semiconductor substrate 100. A width of each of the mold patterns 120 may be smaller than a width of the device isolation pattern 110. The fin-openings 131 may have linear shapes or other shapes known to those of ordinary skill to be relevant to the configuration of the fin-openings 131. Widths of the fin-openings 131 may be substantially equal to each other, for example, a width of the fin-openings 131 at the top surface of the mold patterns 120. A width of the fin-opening 131 may be substantially equal to or smaller than a width of the mold pattern 120.

Additionally, the mold patterns 120 may further include openings 133 that expose top surfaces of the device isolation patterns 110. In some embodiments, the opening 133 may have a width equal to the width of the fin-opening 131. In other embodiments, distances between the mold patterns 120 on each of the first to third active regions 10, 20, and 30 may be substantially uniform. A distance between the mold patterns 120 on the device isolation pattern 110 may be different than the distance between the mold patterns 120 on each of the first to third active regions 10, 20, and 30. In other words, the width of a fin-opening 131 may be different from the width of an opening 133. In other embodiments, the mold patterns 120 may not be formed on the device isolation pattern 110. In yet other embodiments, some of the mold patterns 120 may cover some or all of the top surfaces of the corresponding device isolation patterns 110.

The first insulating layer 111 may be used as an etch stop layer during the anisotropic etching process for the formation of the fin-openings 131 and the openings 133. An over etching process may be performed to expose the semiconductor substrate 100 when the fin-openings 131 are formed, causing surfaces of the semiconductor substrate 100 exposed by the fin-opening 131 to be damaged. The surface damage of the semiconductor substrate 100 may in turn result in deterioration of a crystal property of semiconductor fins formed by an epitaxial growth technique in a subsequent process. Thus, after the fin-openings 131 are formed, a cleaning process may be performed for curing the surfaces of the semiconductor substrate 100 that are exposed by the fin-openings 131. Here, the cleaning process may be performed using an alkaline cleaning solution, for example, including ammonia, hydrogen peroxide, and water.

Referring to FIG. 4, semiconductor fins 140 may be formed in the fin-openings 131 by an epitaxial growth process. The semiconductor fins 140 may fill, or partially fill, the fin-openings 131. Due to the epitaxial growth process, the semiconductor fins 140 may be selectively grown from only the semiconductor substrate 100 exposed by the fin-openings 131. The semiconductor fins 140 may have linear shapes corresponding to the shapes of the fin-openings 131. Since the semiconductor substrate 100 functions as a seed crystal during the epitaxial growth process, the semiconductor fins 140 formed in the fin-openings 131 may have the same crystal structure as the semiconductor substrate 100. In some embodiments, a discontinuous interface in a crystal structure may be formed between the semiconductor substrate 100 and the semiconductor fin 140 by the epitaxial growth process. When the semiconductor fins 140 are formed by the epitaxial growth process, the openings 133 may remain in empty spaces since a seed may not exist in the opening 133 exposing the device isolation pattern 110. In other words, the semiconductor fins 140 may be selectively formed on the first to third active regions 10, 20, and 30.

The semiconductor fins 140 formed by the epitaxial growth process may include silicon (Si), germanium (Ge), or combination thereof The n-type dopants or the p-type dopants may be selectively doped into the semiconductor fins 140 in situ during the epitaxial growth process. For example, p-type dopants, e.g., boron (B), may be doped into the semiconductor fins 140 of one or more NMOS field effect transistors. N-type dopants, e.g., phosphorus (P) or arsenic (Ar), may be doped into the semiconductor fins 140 of one or more PMOS field effect transistors.

Additionally, the semiconductor fins 140 of the NMOS field effect transistors may include a silicon epitaxial layer. The semiconductor fins 140 of the PMOS field effect transistors may include a silicon-germanium epitaxial layer.

In some embodiments, the semiconductor fins 140 may be formed by a selective epitaxial growth (SEG) process using the semiconductor substrate 100 exposed by the mold patterns 120 as a seed. The semiconductor fins 140 formed by the selective epitaxial growth process may have a single-crystalline structure. For example, the silicon (Si) epitaxial layer may be formed using a silicon containing gas such as SiH₄, Si₂H₄, Si₂H₆, and/or SiH₂Cl₂ at a temperature of about 700 degrees Celsius by applying a chemical vapor deposition method. Similarly, a silicon-germanium (SiGe) epitaxial layer may be formed using a mixture gas of the silicon containing gas, e.g., SiH₄, Si₂H₄, Si₂H₆, and/or SiH₂Cl₂ and a germanium containing gas, e.g., GeH₄ and/or GeH.

In other embodiments, the semiconductor fins 140 may be formed using a solid phase epitaxial process. An amorphous semiconductor layer or a poly-crystalline semiconductor layer may be deposited in the fin-openings 131. The amorphous or poly-crystalline semiconductor layer may then be crystallized to form the semiconductor fins 140.

In other embodiments, the semiconductor fins 140 may be formed using a laser-induce epitaxial growth (LEG) process. After an amorphous semiconductor layer is formed in the fin-openings 131, a laser beam such as an excimer laser may be irradiated at the amorphous semiconductor layer. The amorphous semiconductor layer may be crystallized to form the semiconductor fins 140 by irradiating the laser beam.

In other embodiments, the semiconductor fins 140 may be formed by performing a molecular beam epitaxial process.

In the embodiments described above, since the semiconductor fins 140 used as channels of the field effect transistors are formed using the epitaxial growth technique, a current flow in the semiconductor fins 140 may be improved. Thus, electrical characteristics of the field effect transistors may be improved.

In some embodiments, the semiconductor fins 140 grown from the semiconductor substrate 100 may be over-grown, resulting in the fins 140 extending excessively high from than top surfaces of the mold patterns 120. After the epitaxial growth process is performed, a planarization process may be performed to planarize top surfaces of the semiconductor fins 140. As a result, a height T2 of the semiconductor fin 140 from a top surface of the semiconductor substrate 100 may be substantially equal to a height of the mold pattern 120 from the semiconductor substrate 100. The top surfaces of the semiconductor fins 140 may be substantially coplanar with each other. Thus, the semiconductor fins 140 may be formed on the semiconductor substrate 100 having uniform heights with respect to each other. Widths of the semiconductor fins 140 may be substantially equal to each other due to the mold patterns 120 having the uniform distances therebetween. For example, the width of each of the semiconductor fins 140 may be within a range of about 5 nm to about 20 nm. The height T2 of the semiconductor fin 140 may be smaller than a height T1 of the device isolation pattern 110.

A process that controls effective channel widths may be performed for forming a plurality of field effect transistors, for example, first, second, and third transistors, respectively, having different electrical characteristics.

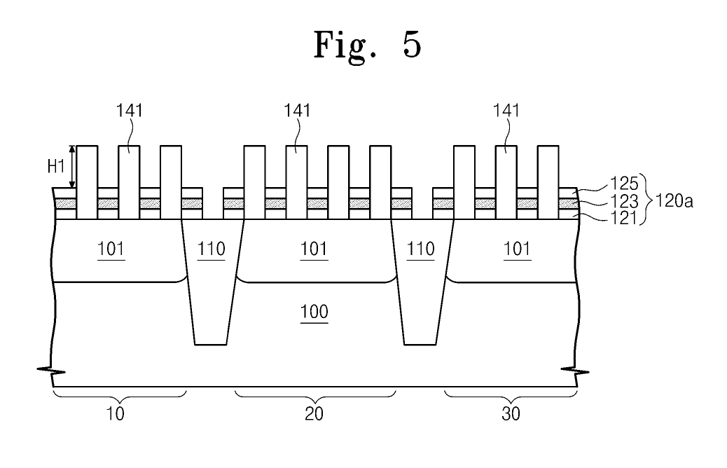

In detail, referring to FIGS. 5 to 8, the mold patterns 120 may have different thicknesses in the first, second, and third active regions 10, 20, and 30 with respect to exposing sidewalls of the semiconductor fins 140. In other words, the top surfaces of the mold patterns 120 may be selectively recessed in the first to third active regions 10, 20, and 30. Since recess depths of the top surfaces of the mold patterns 120 are controlled, exposed areas of the semiconductor fins 140 may vary. As the exposed area of the semiconductor fin 140 becomes increased, an overlap area of the semiconductor fin 140 and a gate electrode 163 may be increased. Thus, the effective channel width of the field effect transistor may be increased. Accordingly, the field effect transistors, each having different electrical characteristics, may be formed according to the exposed areas of the semiconductor fins 140.

In more detail, referring to FIG. 5, the top surfaces of the mold patterns 120 may be recessed by a first depth in the first to third active regions 10, 20, and 30, thereby forming first semiconductor fins 141. The hard mask patterns 127 may be removed to form first semiconductor fins 141 of which top surfaces and portions of sidewalls are exposed. The first semiconductor fins 141 may have a first fin height H1. The first fin height H1 may correspond to a vertical distance from a top surface of a separation structure 120a to a top surface of the first semiconductor fin 141. The first separation structure 120a may be formed between the first semiconductor fins 141 by removing the hard mask patterns 127 of the mold patterns 120. In some embodiments, the first separation structure 120a may consist of first, second, and third insulating patterns 121, 123, and 125 sequentially stacked.

In some embodiments, removing the hard mask patterns 127 may include wet-etching or dry-etching the hard mask patterns 127 using the third insulating patterns 125 as etch stop layers. For example, if the hard mask patterns 127 are formed of silicon nitride, the hard mask patterns 127 may be wet-etched using a phosphoric acid solution. In another example, if the hard mask patterns 127 are formed of silicon oxide, the hard mask patterns 127 may be wet-etched using a standard cleaning-1(SC1) solution, a LAL solution, a HF solution, or the like.

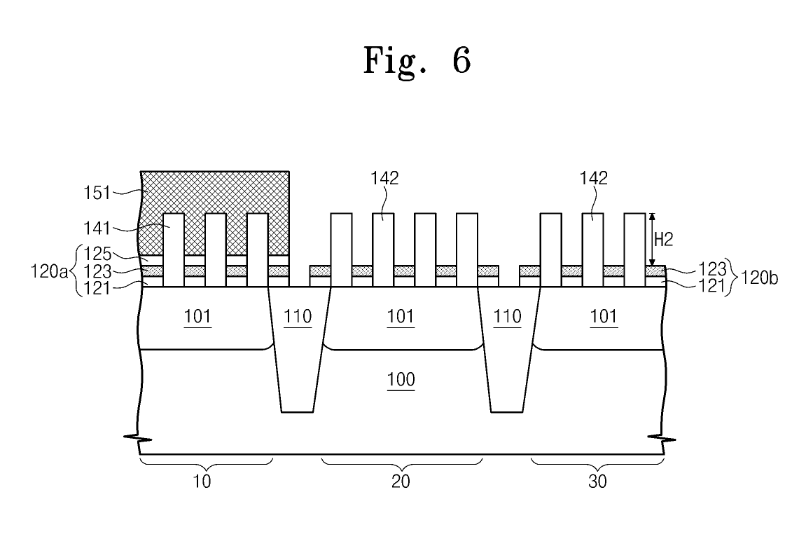

Subsequently, referring to FIG. 6, top surfaces of the first separation structures 120a on the second and third active regions 20 and 30 may be recessed to form second semiconductor fins 142 on the second and third active regions 20 and 30.

In detail, a first mask pattern 151 may be formed to cover the first semiconductor fins 141 and the first fin separation structures 120a of the first active region 10. The third insulating patterns 125 of the second and third active regions 20 and 30 may be removed using the first mask pattern 151 as an etch mask. The third insulating patterns 125 of the second and third active regions 20 and 30 may be selectively etched using an isotropic etching process or an anisotropic etching process. The second insulating patterns 123 may used as etch stop layers. Thus, second semiconductor fins 142 can have exposed areas that are greater than those of the first semiconductor fins 141, and may be formed on the second and third active regions 20 and 30, respectively. The second semiconductor fin 142 may have a second fin height H2 greater than the first fin height H1 of the first semiconductor fins 141. The second fin height H2 may correspond to a vertical distance from a top surface of a second separation structure 120b to a top surface of the second semiconductor fin 142. The second separation structure 120b consisting of the sequentially stacked first and second insulating patterns 121 and 123 may be formed between the second semiconductor fins 142.

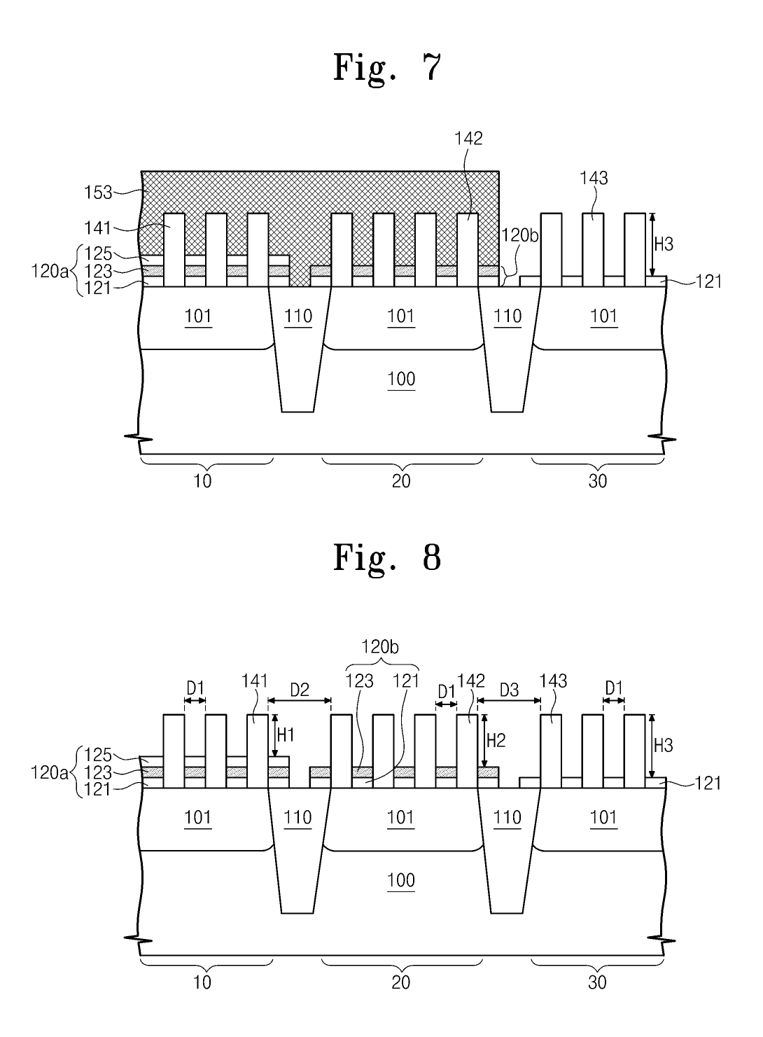

Referring to FIG. 7, top surfaces of the second separation structures 120b on the third active region 30 may be recessed to form third semiconductor fins 143 on the third active region 30.

In detail, a second mask pattern 153 may be formed to cover the first and second active regions 10 and 20. The second insulating patterns 123 of the third active region 30 may be removed using the second mask pattern 153 as an etch mask. The second insulating patterns 123 of the third active region 30 may be selectively etched using an isotropic etching process or an anisotropic etching process. The first insulating patterns 121 of the third active region 30 may be used as etch stop layers. Thus, third semiconductor fins 143 can have exposed areas that are greater than those of the second semiconductor fins 142, and may be formed on the third active regions 30. The third semiconductor fin 143 may have a third fin height H3 greater than the second fin height H2. The third fin height H3 may correspond to a vertical distance from a top surface of a third separation structure to a top surface of the third semiconductor fin 143. The third separation structures may be formed between the third semiconductor fins 143, and may consist of the first insulating pattern 121.

Subsequently, as illustrated in FIG. 8, the second mask pattern 153 is removed, such that the first to third semiconductor fins 141, 142, and 143 of which the exposed areas are different from each other may be formed on the semiconductor substrate 100. In sum, the first to third semiconductor fins 141, 142, and 143, respectively, having different fin heights with respect to each other may be formed on the semiconductor substrate 100. For example, the first semiconductor fin 141 may have the first fin height H1 smaller than the second fin height H2 of the second semiconductor fin 142, and the third semiconductor fin 143 may have the third fin height H3 greater than the second fin height H2 of the semiconductor fin 142.

Additionally, the first semiconductor fins 141 may be formed on the first active region 10. The first separation structures 120a may be disposed between the first semiconductor fins 141. The second semiconductor fins 142 may be formed on the second active region 20. The second separation structures 120b may be disposed between the second semiconductor fins 142. The third semiconductor fins 143 may be formed on the third active region 30. The third separation structures 121 may be disposed between the third semiconductor fins 143. Accordingly, the first through third separation structures 120a, 120b, and 121 may have thicknesses different from each other, respectively. For example, as illustrated in the drawing, the thickness of the first separation structure 120a may be greater than the thickness of the second separation structure 120b and the third separation structure 121 may be smaller than the thickness of the second separation structure 120b. In more detail, the first separation structure 120a may consist of the first to third insulating patterns 121, 123, and 125. The second separation structure 120b may consist of the first and second insulating patterns 121 and 123. The third separation structure may consist of the first insulating pattern 121. The thicknesses of the first to third insulating patterns 121, 123, and 125 may be substantially equal to each other.

As illustrated in FIG. 10, the thicknesses of the first to third insulating patterns 121, 123, and 125 constituting the first to third separation structures 120a, 120b, and 121, respectively, may be different from each other.

Returning to FIG. 8, in some embodiments, a distance D1 between adjacent first semiconductor fins 141, a distance D1 between adjacent second semiconductor fins 142, and a distance D1 between adjacent third semiconductor fins 143 may be substantially equal to each other. Additionally, the widths of the first to third semiconductor fins 141, 142, and 143 may be substantially equal to each other.

A distance D2 between a first semiconductor fin 141 and a second semiconductor fin 142 adjacent the first semiconductor fin 141 may be greater than the distance D1 between two adjacent first semiconductor fins 141 or between two adjacent second semiconductor fins 142. Similarly, a distance D3 between a second semiconductor fin 142 and a third semiconductor fin 143 adjacent the second semiconductor fin 142 may be greater than the distance D1 between two adjacent second semiconductor fins 142 or between two adjacent third semiconductor fins 143.

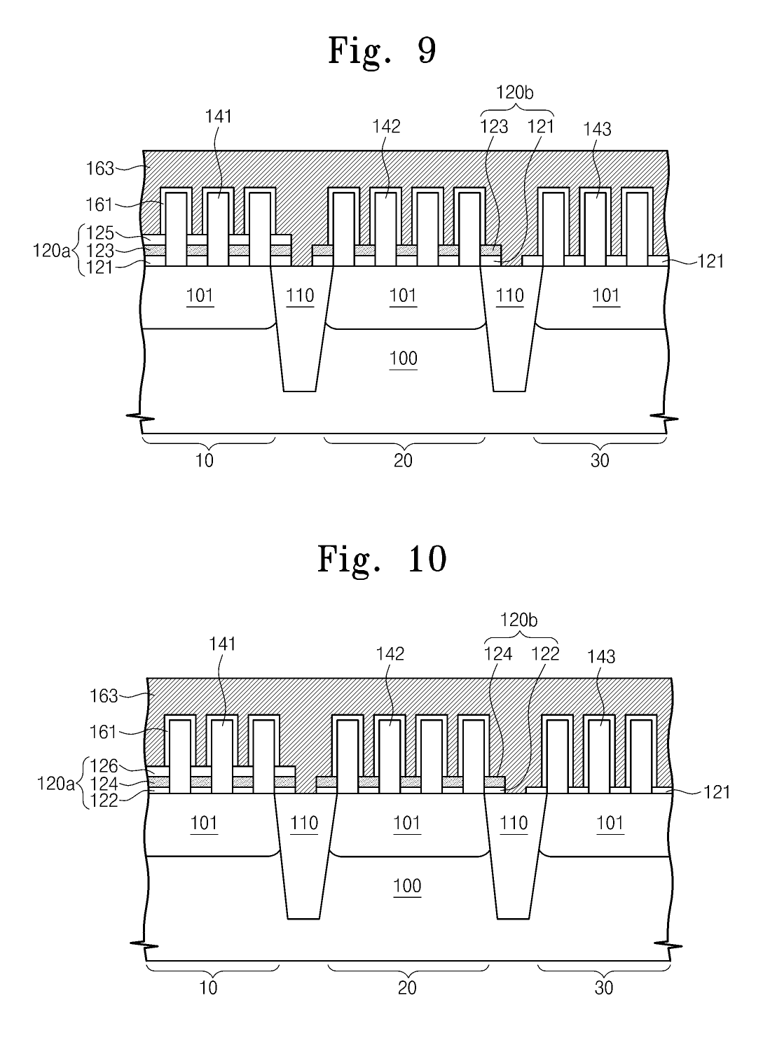

Referring to FIG. 9, a gate electrode 163 is formed to cross over the first to third semiconductor fins 141, 142, and 143.

Before the gate electrode 163 is formed, a gate insulating layer 161 may be formed on the exposed surfaces of the first to third semiconductor fins 141, 142, and 143.

The gate insulating layer 161 may be formed by a thermal oxidation process. The thermal oxidation process may be performed by a dry oxidation method using O₂ gas or a wet oxidation method using H₂O. Alternatively, the gate insulating layer 161 may be formed. Example methods can include but not be limited to a chemical vapor deposition (CVD) method or an atomic layer deposition (ALD) method.

A gate conductive layer may be formed on the gate insulating layer 161. The gate conductive layer may subsequently be patterned to form the gate electrode 163. The gate conductive layer may be formed by a film-formation technique having an excellent step-coverage property, for example, a CVD method or an ALD method. For example, the gate conductive layer may be formed of a poly-crystalline silicon layer highly doped with dopants, a metal layer, e.g., tungsten, nickel, molybdenum, and/or cobalt, a metal silicide layer, or any combinations thereof, e.g., a stacked layer of a highly doped poly-crystalline silicon layer and a nickel-cobalt silicide layer. In other embodiments, the gate electrode 164 may be formed of conductive materials that have work functions that are different from each other on the first to third active regions 10, 20, and 30, respectively.

Overlapped areas between the gate electrode 163 and the first, second, and third semiconductor fins 141, 142, and 143 may be different from each other due to differences between the thicknesses of the first through third separation structures 120a, 120b, and 121.

After the gate electrode 163 is formed, n-type or p-type dopant ions may be implanted into the first to third semiconductor fins 141, 142, and 143 at both sides of the gate electrode 163 to form source/drain regions (not shown). The source/drain regions may be formed to be doped with dopants of a conductivity type opposite to those of the first to third semiconductor fins 141, 142, and 143.

As described above, since the overlapped areas of the gate electrode 163 and the first to third semiconductor fins 141, 142, and 143 are different from each other, fin field effect transistors (finFETs) may be formed on the first to third active regions 10, 20, and 30, respectively. In an embodiment, NMOS field effect transistors are formed on at least one of the first to third active regions 10, 20, and 30 and PMOS field effect transistors are formed on the rest of the first to third active regions 10, 20, and 30. Here, the NMOS and PMOS transistors can be formed to be adjacent to each other. Accordingly, a distance between the NMOS and PMOS transistors may be established by the device isolation patterns 110. Thus, undesirable electrical influences between the NMOS and PMOS transistors may decrease.

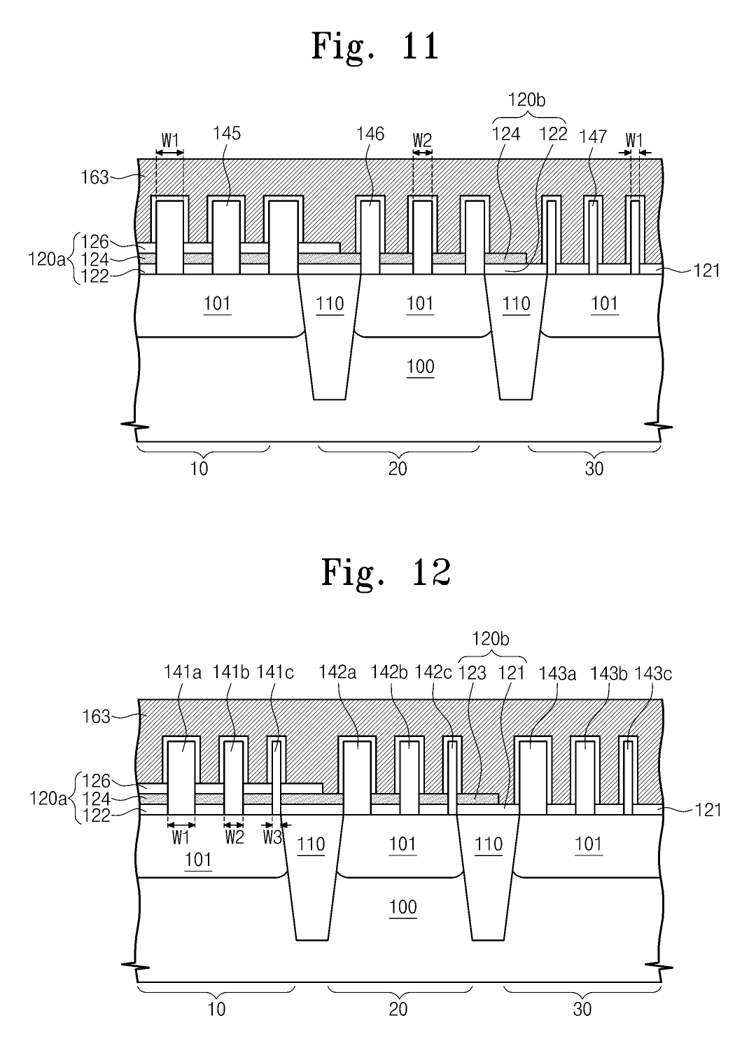

FIGS. 11 and 12 are cross-sectional views illustrating a method of manufacturing a semiconductor device according to other embodiments of the inventive concepts.

Referring to FIG. 11, as described with reference to FIGS. 1 to 9, semiconductor fins 140 of FIG. 2 may be formed using mold patterns 120 of FIG. 4. Top surfaces of the mold patterns 120 of FIG. 4 may be differently recessed according to the first to third active regions 10, 20, and 30. Thus, first through third semiconductor fins 145, 146, and 147 may be formed to have fin heights that are different from each other, respectively. Additionally, in the embodiment illustrated in FIG. 11, widths W1, W2, and W3 of the first, second, and third semiconductor fins 145, 146, 147 may be different from each other. In other words, when the mold patterns 120 are formed in FIG. 3, distances between the mold patterns 120 may be different from each other according to dimensions of the first to third active regions 10, 20, and 30. For example, the widths W1 and W2 of the first semiconductor fin 145 and the second semiconductor fin 146 may be different from each other. The width W1 of the first semiconductor fin 145 may be greater than the width W2 of the second semiconductor fin 146. Additionally, the widths W2 and W3 of the second semiconductor fin 146 and the third semiconductor fin 147 may be different from each other. For example, the width W2 of the second semiconductor fin 146 may be greater than the width W3 of the third semiconductor fin 147.

In the embodiment illustrated in FIG. 12, fin heights of the semiconductor fins may be different from each other according to active regions 10, 20, and 30. Additionally, the semiconductor fins on each of the active regions 10, 20, and 30 may have different widths.

A fin height of each of first semiconductor fins 141a, 141b, and 141c on the first active region 10 may be smaller than a fin height of each of the second semiconductor fins 142a, 142b, and 142c on the second active region 20. Widths W1, W2, and W3 of the first semiconductor fins 14 on the first active region 10 may be different from each other. Additionally, a fin height of each of third semiconductor fins 143a, 143b, and 143c on the third active region 30 may be greater than the fin height of each of the second semiconductor fins 142a, 142b, and 142c, and widths of the third semiconductor fins 143a, 143b, and 143c on the third active region 30 may be different from each other.

In other words, in the embodiment illustrated in FIG. 12, the field effect transistor on one of the semiconductor fins on the semiconductor substrate 100 may have an electrical characteristic that is different from those of field effect transistors on realized on the others of the semiconductor fins on the semiconductor substrate 100. In other words, when a predetermined voltage is applied to the gate electrode 163, a current flowing through one of the semiconductor fins may be different from a current flowing through each of the others of the semiconductor fins.

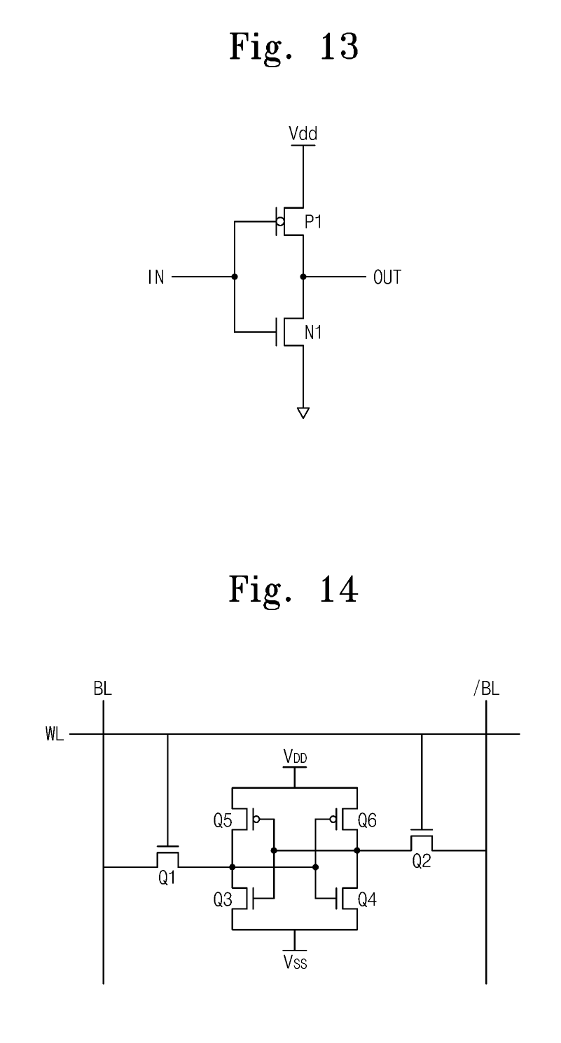

FIG. 13 is a circuit diagram of an inverter including a semiconductor device according to embodiments of the inventive concepts.

The inventor can be a complementary metal-oxide-semiconductor (CMOS) inverter, comprising a PMOS transistor P1 and a NMOS transistor N1. Here, the PMOS transistor P1 and the NMOS transistor N1 may be a finFET manufactured according to embodiments described herein. The PMOS and NMOS transistors P1 and N1 are connected in series between a driving voltage Vdd and a ground voltage GND. An input signal IN is inputted in common to gate electrodes of the PMOS and NMOS transistors P1 and N1. An output signal OUT is outputted from drains of the PMOS and NMOS transistors P1 and N1, which are coupled together. The driving voltage Vdd is applied to a source of the PMOS transistor P1 and the ground voltage GND is applied to a source of the NMOS transistor N1. The CMOS inverter may invert the input signal IN to generate the output signal OUT. In this manner, when the input signal IN is inputted to the CMOS inverter having a logic level ‘1’, the output signal OUT is outputted from the CMOS inverter having a logic level ‘0’. When the input signal IN is inputted to the CMOS inverter having a logic level ‘0’ as, the output signal OUT is outputted from the CMOS inverter having a logic level ‘1’.

FIG. 14 is a circuit diagram of a static random access memory (SRAM) device including a semiconductor device according to embodiments of the inventive concepts.

Referring to FIG. 14, a memory cell of a SRAM device may consist of first and second access transistors Q1 and Q2, first and second driver transistors, or first and second pull-down transistor, Q3 and Q4, and first and second load transistors, or first and second pull-up transistors, Q5 and Q6. Here, the access transistors Q1 and Q2, the driver transistors Q3 and Q4, and the load transistors Q5 and Q6 may be finFETs similar or the same as those manufactured according to embodiments of the inventive concepts.

The sources of the first and second driver transistors Q3 and Q4 can be connected to a ground line V_{SS}. The sources of the first and second load transistors Q5 and Q6 can be connected to a power line V_{DD}.

The first driver transistor Q3 formed of the NMOS transistor and the first load transistor Q5 formed of the PMOS transistor may constitute a first inverter. The second driver transistor Q4 formed of the NMOS transistor and the second load transistor Q6 formed of the PMOS transistor may constitute a second inverter.

Output terminals of the first and second inverters can be connected to a source of the first access transistor Q1 and a source of the second access transistor Q2, respectively. The first and second inverters may be cross-connected to each other to form a latch circuit. In other words, the output terminal of the first inverter can be connected to an input terminal of the second inverter and an input terminal of the first inverter can be connected to the output terminal of the second inverter. Drains of the first and second access transistors Q1 and Q2 can connected to a first bit line BL and a second bit line/BL, respectively.

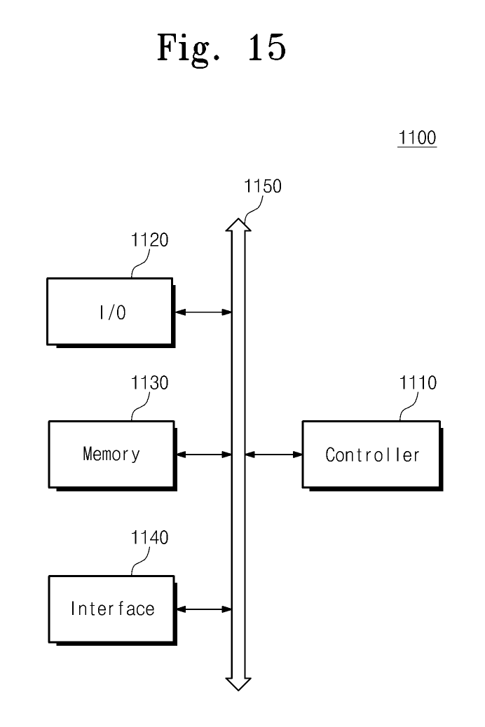

FIG. 15 is a schematic block diagram illustrating an electronic system 1100 including a semiconductor device according to embodiments of the inventive concept. In an embodiment, the electronic system 1100 includes a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may provide a path through which electrical signals are transmitted. The controller 1110 and the memory device 1130 may include the finFETs formed according to one or more embodiments of the inventive concepts.

The controller 1110 may include at least one of a microprocessor, a digital signal processor, a microcontroller, or other logic devices known to those of ordinary skill in the art. The other logic devices may have a similar function to any one of the microprocessor, the digital signal processor, and the microcontroller. The I/O unit 1120 may include a keypad, a keyboard, and/or a display unit.

The memory device 1130 may store data and/or commands. The memory device 1130 may include a flash memory device, a DRAM device, and/or a SRAM device.

The interface unit 1140 may transmit electrical data to a communication network or may receive electrical data from a communication network. The interface unit 1140 may be operated by a wireless connection or physical connection such as a cable that can transmit electronic signals. For example, the interface unit 1140 may include an antenna for wireless communication or a transceiver for cable communication. Although not shown in the drawings, the electronic system 1100 may further include a fast DRAM device and/or a fast SRAM device which is constructed and arranged to include a cache memory for improving an operation of the controller 1110.

The electronic system 1100 may be applied to a personal digital assistant (PDA), a portable computer, a web tablet, a wireless phone, a mobile phone, a digital music player, a memory card, or other electronic devices. The other electronic devices to which the electronic system 1100 may be applied may receive or transmit information data by a wireless connection.

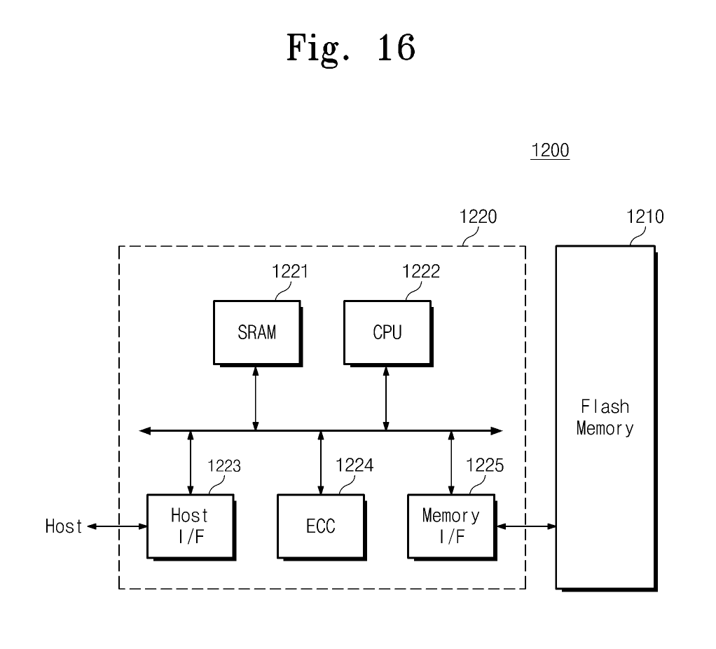

FIG. 16 is a schematic block diagram illustrating a memory card 1200 including a semiconductor device according to embodiments of the inventive concept.

Referring to FIG. 16, a memory card 1200 according to an embodiment of the inventive concept may include a memory device 1210. The memory device 1210 may include a flash memory device, a DRAM device, and/or a SRAM device. The memory card 1200 may include a memory controller 1220 that controls data communication between a host and the memory device 1210. The memory device 1210 and the controller 1220 may include one or more fin field effect transistors manufactured according to embodiments of the inventive concepts.

The memory controller 1220 may include a central processing unit (CPU) 1222 that controls overall operations of the memory card 1200. In addition, the memory controller 1220 may include an SRAM device 1221 that provides an operation memory of the CPU 1222. The memory controller 1220 may further include a host interface unit 1223 and a memory interface unit 1225. The host interface unit 1223 may include a data communication protocol for providing data exchanges between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read from the memory device 1210. Even though not shown in the drawings, the memory card 1200 may further include a read only memory (ROM) device that stores code data for communicating with the host. The memory card 1200 may be used as a portable data storage card. Alternatively, the memory card 1200 may include solid state disks (SSD) which are used as hard disks of computer systems.

According to the manufacturing methods of embodiments of the inventive concepts, it is possible to form fin field effect transistors that respectively have effective channel widths that are different from each other. Since the epitaxial layer provides channels of the fin field effect transistors, it is possible to improve the electrical characteristics of the fin field effect transistors. Additionally, it is possible to decrease an electrical influence between fin field effect transistors, which have different electrical characteristics with respect to each other.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of manufacturing a semiconductor device, comprising:
constructing and arranging a semiconductor substrate to include a first active region and a second active region;
forming mold patterns on the semiconductor substrate, the mold patterns having openings that expose a top surface of the semiconductor substrate;
forming a plurality of first semiconductor fins in openings at the first active region and a plurality of second semiconductor fins in openings at the second active region;
selectively recessing top surfaces of the mold patterns, wherein a recessed depth of the mold patterns on the first active region is different than a recessed depth of the mold patterns on the second active region; and
forming a gate electrode over the first and second semiconductor fins, wherein a distance between a first semiconductor fin of the plurality of first semiconductor fins and a second semiconductor fin of the plurality of second semiconductor fins adjacent the first semiconductor fin is greater than a distance between two or more first semiconductor fins of the plurality of first semiconductor fins that are adjacent each other.

2. The method of claim 1, wherein distances between the mold patterns are substantially uniform with respect to each other along a surface of the semiconductor substrate.

3. The method of claim 1, wherein the semiconductor substrate includes a device isolation pattern that defines the first and second active regions.

4. The method of claim 3, wherein the device isolation pattern is between the first semiconductor fin and the second semiconductor fin.

5. The method of claim 3, wherein a width of the device isolation pattern is greater than a distance between the two or more first semiconductor fins adjacent each other.

6. The method of claim 3, wherein a height of the device isolation pattern is greater than each vertical distance extending from a top surface of the semiconductor substrate to a top surface of the first and second semiconductor fins.

7. The method of claim 1, wherein forming the first and second semiconductor fins comprises:
performing a selective epitaxial growth process using the semiconductor substrate exposed by the openings of the mold patterns as a seed.

8. The method of claim 1, wherein vertical distances from a top surface of the semiconductor substrate to top surfaces of the first and second semiconductor fins, respectively, are substantially uniform.

9. The method of claim 1, wherein forming the mold patterns comprises:
stacking a first insulating layer, a second insulating layer, and a hard mask layer, each having an etch selectivity; and
patterning the hard mask layer, the second insulating layer, and the first insulating layer to form the mold patterns, each of the mold patterns including a first insulating pattern, a second insulating pattern, and a hard mask pattern sequentially stacked.

10. The method of claim 9, wherein selectively recessing the top surfaces of the mold patterns comprises:
exposing top surfaces of the second insulating patterns at the first and second active regions; and
exposing top surfaces of the first insulating patterns at the second active region.

11. A method of manufacturing a semiconductor device, comprising:
providing a semiconductor substrate including a first active region and a second active region, the first and second active regions defined by device isolation patterns;
forming a plurality of mold patterns, the mold patterns having openings that expose the semiconductor substrate of the first and second active regions;
performing an epitaxial growth process to form semiconductor fins in the openings, respectively;
selectively recessing top surfaces of the mold patterns to expose sidewalls of the semiconductor fins; and
forming a gate electrode over the semiconductor fins having the exposed sidewalls, wherein exposing the sidewalls of the semiconductor fins comprises:
recessing the top surfaces of the mold patterns on the first active region by a first depth to form first semiconductor fins; and
recessing the top surfaces of the mold patterns on the second active region by a second depth greater than the first depth to form second semiconductor fins.

12. The method of claim 11, wherein a width of each of the device isolation patterns is greater than a distance between the first semiconductor fins adjacent to each other.

13. The method of claim 11, wherein the mold patterns expose top surfaces of the device isolation patterns.

14. The method of claim 11, wherein the first semiconductor fin is adjacent the second semiconductor fin, and wherein a distance between the first semiconductor fin and the second semiconductor fin is greater than a distance between two first semiconductor fins adjacent each other.

15. The method of claim 11, wherein vertical distances from a top surface of the semiconductor substrate to top surfaces of the first and second semiconductor fins, respectively, are substantially equal to each other.

16. A method of manufacturing a semiconductor device, comprising:
forming a first active region and a second active region at a substrate;
forming at least one insulating layer on the substrate;
forming at least one first opening in the at least one insulating layer, the at least one first opening exposing the substrate at the first active region;
forming at least one second opening in the at least one insulating layer, the at least one second opening exposing the substrate at the second active region;
forming a fin of a first field effect transistor (FinFET) in the at least one first opening; and
forming a fin of a second FinFET in the at least one second opening, wherein a channel width at the first FinFET is different than a channel width at the second FinFET.

17. The method of claim 16, further comprising:
forming a plurality of first semiconductor fins at the at least one first opening at the first active region; and
forming a plurality of second semiconductor fins at the at least one second opening at the second active region, wherein a distance between a first semiconductor fin of the plurality of first semiconductor fins and a second semiconductor fin of the plurality of second semiconductor fins adjacent the first semiconductor fin is greater than a distance between two or more first semiconductor fins of the plurality of first semiconductor fins that are adjacent each other.

18. The method of claim 16, further comprising:
etching the at least one insulating layer to form mold patterns on the substrate, wherein the mold patterns are separated from each other by the at least one first opening and the at least one second opening; and
selectively recessing top surfaces of the mold patterns, wherein a recessed depth of mold patterns on the first active region is different than a recessed depth of mold patterns on the second active region.

19. The method of claim 16, wherein the first FinFET and the second FinFET have different electrical characteristics with respect to each other.

20. The method of claim 20, further comprising:
forming a first separation structure from the at least one insulating layer, the first separation structure between the plurality of first semiconductor fins;
forming a second separation structure from the at least one insulating layer, the second separation structure between the plurality of second semiconductor fins, wherein a vertical distance from a top surface of the first separation structure to a top surface of the first semiconductor fin is different than a vertical distance from a top surface of the second separation structure to a top surface of the second semiconductor fin.
